(19) United States
(12) Patent Application Publication
(10) Pub. No.: US 2016/0254404 A1
(43) Pub. Date: Sep. 1, 2016

(54) PHOTOVOLTAIC PANEL AND METHOD FOR PRODUCING SAME

(71) Applicant: DAS ENERGY GMBH, Wiener Neustadt (AT)

(72) Inventors: Christian DRIES, Wiener Neustadt (AT); Manfred ZIPPER, Wiesmath (AT); Boris KRASNIK, Markt Piesting (AT); Johann HARTER, Dresden (DE)

(73) Assignee: DAS ENERGY GMBH, Wiener Neustadt (AT)

(21) Appl. No.: 15/028,185

(22) PCT Filed: Oct. 16, 2014
(86) PCT No.: PCT/EP2014/072179

§ 371 Date: Apr. 8, 2016

(30) Foreign Application Priority Data
Oct. 17, 2013 (EP) 13189147.5

(51) Int. Cl. H01L 31/048; H01L 31/18

(52) U.S. Cl. CPC H01L 31/0481; H01L 31/0488; H01L 31/18

(57) ABSTRACT

A photovoltaic panel (1) with at least one solar cell (2) covered with a transparent composite material (5a, 5b) at least at a side (3) facing towards the light and an opposite side (4) facing away from the light, wherein the composite material (5a, 5b) is a plastic (7a, 7b) on the basis of an acrylate containing epoxy groups, reinforced with glass fibers (6a, 6b).

The present invention relates to a photovoltaic panel with at least one solar cell covered with a transparent composite material at least at a side facing towards the light and an opposite side facing away from the light. The present invention further relates to a method for manufacturing the photovoltaic panel.

Photovoltaic panels for obtaining electrical energy from solar radiation have been generally known. For converting the solar energy to electrical energy, theses panels comprise solar cells, in particular specifically modified inorganic semiconductors or semiconductor wafers, respectively, which are usually manufactured of appropriately doped silicon and are joined to form modules. It has also been known to use organic semiconductors or vapor-deposited thin semiconductor layers containing cadmium telluride, copper/indium/(di)selenide or copper/indium/gallium/sulphide/selenide or amorphous silicon. The modules are laminated by means of appropriate devices, incorporated in housings, and covered with a glass plate to protect them from environmental influences such as, for instance, rain and snow. The photovoltaic panels manufactured this way may be installed in places suitable for the conversion of solar radiation into electrical energy. The photovoltaic panels, however, are in general designed to be rigid, substantially inflexible and to have much weight, wherein the weight is determined predominantly by the housing and the cover of the photovoltaic modules.

In prior art, photovoltaic panels have been known which have already been improved with respect to some of these disadvantages.

WO 2013/119113 A1 discloses a photovoltaic panel whose solar cells are protected from environmental influences, for instance, mechanical damage, by a sheath of a transparent composite material containing a fiber reinforced thermoplastic polymer, in particular polymethyl methacrylate. For manufacturing, the panel is placed on a mold along with a tissue of reinforcement fibers, and liquid thermoplastic polymer is introduced into the mold at 150 to 250° C. and a pressure of 1 to 500 bar. As compared to panels with a glass cover, it is possible to manufacture the panel to be thinner and to have lower weight, and to have high mechanical strength. However, molds of appropriate design are required for manufacturing uneven and/or curved panels.

DT 24 45 642 A1 relates to a solar cell generator, wherein the solar cells and their connecting elements are enclosed on all sides by a single material. Polyester resin, acrylic resin, polymeric acrylic polyester and epoxy resin with or without glass fiber reinforcement as well as thermoplastic resin of the group of polycarbonates are mentioned as materials. For manufacturing, the solar cells are placed on a glass fiber layer soaked with synthetic resin and are covered with a second glass fiber layer soaked with the same synthetic resin, so that the solar cells are enclosed by a uniform sheath after curing of the synthetic resin. However, the document does not disclose any details with respect to the strength, the thickness or the weight of the solar cell generator.

EP 0 071 181 A2 discloses a flexible photovoltaic solar module with solar cells. Here, at least the solar cells are underlaid by laminar stiffenings and/or covered with a stiffening thin glass layer for their protection while the rest of the solar module face is not stiffened. The solar module comprises a flexible carrier element such as, for instance, a metal fabric, a fiber reinforced flexible composite material, or a reinforced plastic foil. The solar cells are surrounded by plastic foils or flexible composite materials. The complex structure and a restricted flexibility of the solar module are of disadvantage here.

It is an object of the invention to provide a photovoltaic panel which avoids or at least reduces the disadvantages of prior art and which has low weight and small thickness. In particular, the photovoltaic panel is intended to have a design as flexible as possible, and the solar cells are intended to be protected from environmental influences such as mechanical damage, for instance, by hail. Moreover, the panel is intended to have an effectiveness as high as possible and to be manufactured in a simple and cost-efficient manner.

In accordance with the invention the object is solved in that the photovoltaic panel with at least one solar cell covered with a transparent composite material at least at a side facing towards the light and an opposite side facing away from the light is characterized in that the composite material is a glass fiber reinforced plastic on the basis of an acrylate containing epoxy groups. The at least one solar cell is thus covered substantially completely with the composite material at its front side and at its rear side. Preferably, the at least one solar cell is enclosed completely by the composite material. If, in the further course of the instant description, reference is made to a solar cell, this means the photovoltaically active element converting solar light incident on its surface into electrical energy. Furthermore, the side facing towards the light means the side of the solar cell and/or the photovoltaic panel which faces towards the solar radiation when the photovoltaic panel is used as intended. It is to be understood that light may also strike the side facing away from the light (rear side) unless it has been covered to be impermeable to light. Also, a plurality of solar cells may be joined to form a module and may be covered by the composite material and/or be enclosed therein. If glass fibers are referred to in the instant description, this means in general transparent reinforcement fibers comprising the required strength to reinforce the plastic on the basis of an acrylate containing epoxy groups. Accordingly, in the scope of the instant description the reinforcement fibers designated as glass fibers need not necessarily be manufactured of glass. In particular, the glass fibers may consist of a transparent plastic having substantially the same optical refraction index as the plastic on the basis of an acrylate containing epoxy groups. The glass fibers in the composite material cause a mechanical reinforcement of the panel, but promote, due to their transparency, also a high light permeability of the composite material. Both the glass fibers and the plastic on the basis of an acrylate containing epoxy groups cause sufficient electrical insulation of the live components of the panel which are surrounded by the composite material. The composite material insulates the components covered therewith and/or completely enclosed therewith from the environment. In particular, the panel is given high strength and high resistance also with respect to mechanical influences. Its high impact strength offers appropriate protection, for instance, from hail or other mechanical influences. An own housing into which the modules have to be incorporated for achieving the required strength and for protection from environmental influences, or the covering with a glass plate, respectively, is thus not necessary. The panel according to the invention may in particular be manufactured to be particularly thin and to have low weight. Due to the high transparency of the composite material, a high effectiveness of the panel is additionally achieved. Surprisingly, the transparency of the composite material is substantially not influenced by the epoxy groups. It is of particular advantage that the panel is also flexible, so that it is easy for it to assume the shape of different uneven faces on which it is to rest. The panel may comprise further layers, for instance, organic polymeric materials, at its front side and/or rear side for further improving the protection from environmental influences. Thus, an ETFE (ethylene tetrafluoroethylene) foil may be applied on the front side facing towards the light, and an EPE (EVA—polyester—EVA) film layer may be applied on the rear side facing away from the light. Furthermore, additional polymer layers may be added between the individual materials such as, for instance, a layer of EVA (ethylene vinyl acetate) between the side of the solar cells facing towards the light and the layer of composite material arranged at the front side of the panel.

In accordance with a preferred embodiment of the present invention, the acrylate containing epoxy groups is glycidyl methacrylate. If the glass fibers have a filament diameter in the range of 3 to 15 μm, preferably in the range of 6 to 12 μm, and particularly preferred of 9 μm, the reinforcement layer formed by the glass fibers and hence also the layer of composite material may be designed to be particularly thin and flexible and to have low weight.

Preferably, the glass fibers at the side of the at least one solar cell facing towards the light are designed as a fabric with a weight in the range of 50 to 300 g/m², preferably in the range of 100 to 200 g/m², and particularly preferred in the range of 160 to 165 g/m². The design of the glass fibers as a fabric increases the loading capacity of the composite material and hence of the panel. Moreover, such a light fabric also enables the manufacturing of a panel with low weight.

It is particularly preferred if the fabric comprises at the side of the at least one solar cell facing towards the light a warp yarn and a weft yarn with a yarn count in the range of 30 to 120 tex, preferably in the range of 45 to 100 tex, and particularly preferred in the range of 60 to 70 tex. A tex means 1 gram per 1000 meters. Such a fabric enables a thin and light design of the composite material at the side of the at least one solar cell facing towards the light.

In accordance with a further preferred embodiment of the invention the glass fibers at the side of the at least one solar cell facing away from the light are designed as a fabric with a weight in the range of 100 to 600 g/m², preferably in the range of 200 to 500 g/m², and particularly preferred of 390 g/m². The fabric arranged at the side of the at least one solar cell facing away from the light may in particular have a heavier and hence also a stronger design than the fabric arranged at the side of the at least one solar cell facing towards the light. In this way, the panel may have a particularly strong reinforcement at the rear side while the light incident on the solar cells through the front side of the panel penetrates the thinner fabric layer with as little loss as possible.

Preferably, at the side of the at least one solar cell facing away from the light, the fabric comprises a warp yarn joined from 1 to 9, preferably 3 to 7, particularly preferred 5 yarns and having a yarn count in the range of 30 to 120 tex, preferably in the range of 45 to 100 tex, and particularly preferred in the range of 60 to 70 tex, and a weft yarn with a yarn count in the range of 100 to 450 tex, preferably in the range of 200 to 350 tex, and particularly preferred in the range of 270 to 280 tex. By joining several yarns to form a warp yarn, its strength is increased. The yarn count of the warp yarn and of the weft yarn additionally enables a thin design of the composite material at the side of the at least one solar cell facing away from the light.

In accordance with the invention the object is further solved in that a method for manufacturing the afore-described photovoltaic panel comprises the steps of:
applying powdered acrylate containing epoxy groups on a first fabric of glass fibers,
placing at least one solar cell and electrical branch lines connected with the solar cell as well as possible connection lines connecting a plurality of solar cells on the powdered acrylate containing epoxy groups or on a layer of ethylene vinyl acetate applied on the powdered acrylate containing epoxy groups,
placing a second fabric of glass fibers on the at least one solar cell, the branch lines and the possible connection lines,
applying powdered acrylate containing epoxy groups on the second fabric, and
laminating the entire structure.

By the laminating, the powdered acrylate containing epoxy groups is fused and is transparent, and the individual layers of the structure are joined to one another. In accordance with this method, the at least one solar cell or the solar cells, respectively, is/are covered with a transparent composite material and/or enclosed by the composite material at the side facing towards the light and the side facing away from the light after laminating. Moreover, the branch lines of the solar cell(s) and possible connection lines connecting a plurality of solar cells are also enclosed at least partially with the transparent composite material. The composite material here comprises the respective glass fiber fabric and the acrylate containing epoxy groups. The structure is simple and cost-efficient to manufacture. The powdered acrylate containing epoxy groups is preferably applied on the respective fabric with a powder spreader and may moreover be metered appropriately. The acrylate containing epoxy groups may partially penetrate into the mesh openings of the fabric and may thus fuse better around the glass fibers of the fabric during laminating. It is pointed out that the powder may have very small grain sizes and that the term “powder” may therefore also comprise a “fine powder”. Moreover, a layer of ethylene vinyl acetate may be provided between the powdered acrylate containing epoxy groups applied on the first fabric and the solar cell and/or its branch lines and possible connection lines, as an additional protection from environmental influences.

Preferably, glycidyl methacrylate is applied as an acrylate containing epoxy groups. After laminating, the glycidyl methacrylate is transparent, wherein its transparency remains substantially unchanged and does not become yellow during the lifetime of the photovoltaic panel. Moreover, it gives, along with the glass fiber fabrics, the panel high strength and remains yet flexible.

It is particularly preferred if laminating takes place in a temperature range of 150 to 200° C. at a pressure of up to 500 mbar and under a vacuum of 0 to 300 mbar. The pressure of up to 500 mbar is exerted on the layers of the structure being under the vacuum mentioned. For instance, the pressure may be applied on a plate acting on the layers subjected to the vacuum. Without referring to a particular theory it is assumed that, by applying the acrylate containing epoxy groups in powdered form on the fabrics, ventilation channels remain in the fabrics which are initially not obstructed by the powder and which contribute, on application of the vacuum, to avoiding air locks in the laminated composite material practically completely.

In accordance with a further advantageous embodiment of the invention, the glass fibers of the first and of the second fabric are at least partially coated with a finish as an adhesion agent prior to their being placed. Since the finish serves as an adhesion agent, the connection between the glass fibers and the powdered acrylate containing epoxy groups is improved.

In order to further improve the connection between the glass fibers and the powdered acrylate containing epoxy groups, the first and second fabrics, after the respective applying of the powdered acrylate containing epoxy groups, are tempered in a temperature range of 70 to 120° C., preferably in a temperature range of 85 to 110° C., and particularly preferred at 100° C., and at a pressure of up to 500 mbar.

It is particularly advantageous if powdered acrylate containing epoxy groups with a grain size in the range of 10 to 500 μm, preferably in the range of 25 to 100 μm, and particularly preferred in the range of 40 to 50 μm is applied on the first and second fabrics. The suitable choice of the grain size makes it possible that the powder applied on the fabric partially penetrates into the mesh openings of the fabric and thus neither trickles excessively in the case of too small grains nor comes to lie exclusively on the fabric and above the meshes in the case of too large grains. In this manner the adhesion between the powder and the fabric is improved additionally.

If powdered acrylate containing epoxy groups is applied on the first and second fabrics with an optical refraction index that is substantially equal to that of the glass fibers after laminating, a composite material with particularly high transparency and hence a photovoltaic panel with correspondingly high effectiveness is achieved.

It is pointed out that the photovoltaic panel may be used both for the conversion of light incident on the side of the panel facing towards the solar radiation (front side) and of possible light incident on the opposite side facing away from the solar radiation (rear side). This is enabled inter alia by the transparent composite material both at the side facing towards the solar radiation and at the side facing away from the solar radiation. The panels may be manufactured in almost any shapes. In particular, the panel is bendable and has a bending radius of 300 mm or more. For instance, a panel manufactured in accordance with the invention and having a performance of 240 Wp (60 cells) was mounted on a rotating column with a diameter of 1000 mm. The panels may be mounted on solid or on flexible undergrounds. When having a breadth of 1 m and a length of 2 m, panels in accordance with the invention comprise, for instance, a weight of less than 4 kg. When using wafers (photovoltaic cells) with a thickness of 0.2 mm, the panels have, for instance, a thickness of approximately 1 mm. The mechanical strength of these panels was measured with 111.9 N/mm² for the tensile strain. The bending strength was measured with approximately 168.6 N/mm².

A further panel with a thickness of 1.2 mm and a size of 340×515 mm, consisting of 6 cells with a dissipation of copper network and an electrical performance of 24 W at standard test conditions had a weight of 315 g.

Another panel with a thickness of 1.1 mm and an area of 980 mm×1678 mm, consisting of 60 wafers linked with each other via appropriate contacts, with a performance of 240 Wp at standard test conditions had a weight of 2.9 kg.

When two-dimensionally filled with photovoltaically active cells, panels according to the invention comprise between 1 kg/m² and 9 kg/m², preferably under 2.5 kg/m². The thickness of the panels is preferably between 0.5 mm and 3 mm, in particular under 1 mm, if the thickness of the photovoltaically active materials is 0.2 mm. The panels may be manufactured with dimensions of several meters in length and several meters in breadth, wherein the preferred size is between 1 and 3 meters in length and between 0.5 and 2 meters in breadth.

An example of glycidyl methacrylate is Tiger Drylac© 250/00108 clear by TIGER Drylac U.S.A., Inc. Examples of glass fiber fabrics are
a glass filament fabric with 163 g/m² at the side of the panel facing towards the light, with warp and weft yarn EC9 68 of E-glass with continuous filaments with a filament diameter of 9 μm and a yarn count of 68 tex=68 g/1000 m
a glass filament fabric with 390 g/m² (style 1989) at the side of the panel facing away from the light, with a warp yarn EC9 68×5t0 of E-glass with continuous filaments with a filament diameter of 9 μm and a yarn count of 68 tex, wherein 5 yarns are joined to one in an untwisted manner, and with a weft yarn EC 9 272 of E-glass with continuous filaments with a filament diameter of 9 μm and a yarn count of 272 tex.

In the following, the invention will be explained in more detail by means of preferred, non-restricting embodiments with reference to the drawing.

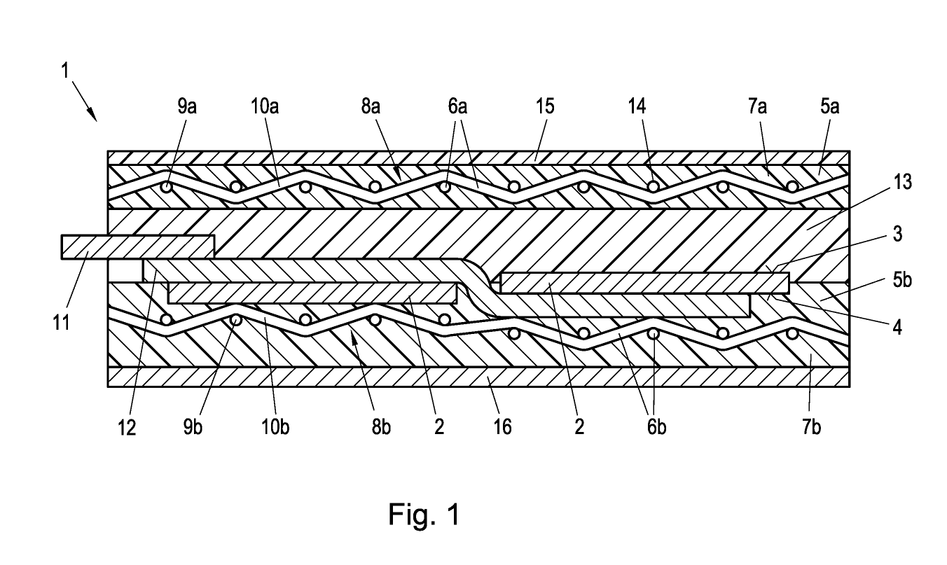

FIG. 1 illustrates a cross-sectional view of a photovoltaic panel in accordance with the invention.

FIG. 1 illustrates in particular a photovoltaic panel 1 with two solar cells 2 covered with a transparent composite material 5a, 5b at least at a side 3 facing towards the light and an opposite side 4 facing away from the light. The composite material 5a, 5b is a plastic 7a, 7b on the basis of an acrylate containing epoxy groups, reinforced with glass fibers 6a, 6b. The glass fibers 6a at the side 3 of the solar cells 2 facing towards the light are designed to form a first fabric 8a with a warp yarn 9a and a weft yarn 10a. Likewise, the glass fibers 6b at the side 4 of the solar cells 2 facing away from the light are designed to form a second fabric 8b with a warp yarn 9b and a weft yarn 10b. Although the glass fibers 6a and 6b and/or the fabrics 8a and 8b are illustrated in equal size and/or strength, this is by no means intended as a restriction. It is to be understood that the glass fibers 6a and 6b and thus also the fabrics 8a and 8b may have different diameters and/or thicknesses. It is in particular possible to arrange a plurality of first fabrics 8a and/or a plurality of second fabrics 8b on top of each other so as to obtain stronger fabric layers altogether. Moreover, the cross-section of the glass fibers 6a, 6b is not restricted to the circular shape illustrated. The solar cells 2 comprise an electrical branch line 11 and are electrically connected with each other via a connection line 12. As may further be gathered, a layer 13 of ethylene vinyl acetate is positioned between the side 3 of the solar cells 2 facing towards the light and the composite material 5a. The glass fibers 6a, 6b are coated with a finish 14 serving as an adhesion agent. Moreover, the panel 1 comprises an ETFE (ethylene tetrafluoroethylene) foil 15 at the front side facing towards the light and a foil 16 at the rear side facing away from the light for protection from environmental influences, in particular for protection from moisture and UV radiation, and for electrical insulation. An example of the foil 16 is 500 DUN-Solar™ EPE sw, by DUNMORE Europe GmbH, Germany, on the basis of polyethyleneterephthalat.

1. A photovoltaic panel (1) with at least one solar cell (2) covered with a transparent composite material (5a, 5b) at least at a side (3) facing towards the light and an opposite side (4) facing away from the light, characterized in that the composite material (5a, 5b) is a plastic (7a, 7b) on the basis of an acrylate containing epoxy groups, reinforced with glass fibers (6a, 6b).

2. The photovoltaic panel (1) according to claim 1, characterized in that the acrylate containing epoxy groups is glycide methacrylate.

3. The photovoltaic panel (1) according to claim 1 or 2, characterized in that the glass fibers (6a, 6b) have a filament diameter in the range of 3 to 15 μm, preferably in the range of 6 to 12 μm, and particularly preferred of 9 μm.

4. The photovoltaic panel (1) according to claim 3, characterized in that the glass fibers (6a) at the side of the at least one solar cell (2) facing towards the light are designed to form a fabric (8a) with a weight in the range of 50 to 300 g/m², preferably in the range of 100 to 200 g/m², and particularly preferred in the range of 160 to 165 g/m².

5. The photovoltaic panel (1) according to claim 4, characterized in that the fabric (8a) comprises a warp yarn (9a) and a weft yarn (106a) with a yarn count in the range of 30 to 120 tex, preferably in the range of 45 to 100 tex, and particularly preferred in the range of 60 to 70 tex.

6. The photovoltaic panel (1) according to any of claims 3 to 5, characterized in that the glass fibers (6b) at the side (4) of the at least one solar cell (2) facing away from the light are designed to form a fabric (8b) with a weight in the range of 100 to 600 g/m², preferably in the range of 200 to 500 g/m², and particularly preferred of 390 g/m².

7. The photovoltaic panel (1) according to claim 6, characterized in that the fabric (8b) comprises a warp yarn (9b) consisting of 1 to 9, preferably 3 to 7, particularly preferred 5, joined yarns with a yarn count in the range of 30 to 120 tex, preferably in the range of 45 to 100 tex, and particularly preferred in the range of 60 to 70 tex, and a weft yarn (10b) with a yarn count in the range of 100 to 450 tex, preferably in the range of 200 to 350 tex, and particularly preferred in the range of 270 to 280 tex.

8. A method for manufacturing a photovoltaic panel (1) according to any of claims 1 to 7, comprising the steps of:
applying powdered acrylate containing epoxy groups on a first fabric (8a) of glass fibers (6a),
placing at least one solar cell (2) and electrical branch lines (11) connected with the solar cell (2) as well as possible connection lines (12) connecting a plurality of solar cells (2) on the powdered acrylate containing epoxy groups or on a layer (13) of ethylene vinyl acetate applied on the powdered acrylate containing epoxy groups,
placing a second fabric (8b) of glass fibers (6b) on the at least one solar cell (2), the branch lines (11) and the possible connection lines (12),
applying powdered acrylate containing epoxy groups on the second fabric (8b), and
laminating the entire structure.

9. The method according to claim 8, characterized in that glycidyl methacrylate is applied as an acrylate containing epoxy groups.

10. The method according to claim 9, characterized in that laminating takes place in a temperature range of 150 to 200° C., at a pressure of up to 500 mbar and under a vacuum of 0 to 300 mbar.

11. The method according to any of claims 8 to 10, characterized in that the glass fibers (6a, 6b) of the first and second fabrics (8a, 8b) are coated at least partially with a finish (14) as an adhesion agent prior to their placing.

12. The method according to any of claims 8 to 11, characterized in that the first and second fabrics (8a, 8b) are tempered, after the respective application of the powdered acrylate containing epoxy groups, in a temperature range of 70 to 120° C., preferably in a temperature range of 85 to 110° C., and particularly preferred at 100° C. and at a pressure of up to 500 mbar.

13. The method according to any of claims 8 to 12, characterized in that powdered acrylate containing epoxy groups is applied on the first and second fabrics (8a, 8b) with a grain size in the range of 10 to 500 μm, preferably in the range of 25 to 100 μm, and particularly preferred in the range of 40 to 50 μm.

14. The method according to any of claims 8 to 13, characterized in that powdered acrylate containing epoxy groups is applied on the first and second fabrics (8a, 8b) with an optical refraction index substantially equal to that of the glass fibers (6a, 6b) after laminating.
